(19) United States
(12) Patent Application Publication
(10) Pub. No.: US 2025/0248098 A1
(43) Pub. Date: Jul. 31, 2025

(54) SEMICONDUCTOR DEVICE AND METHOD OF MANUFACTURING THE SAME

(71) Applicant: Renesas Electronics Corporation, Tokyo (JP)

(72) Inventors: Takahiro OHARA, Tokyo (JP); Takahiro MARUYAMA, Tokyo (JP)

(21) Appl. No.: 18/971,188

(22) Filed: Dec. 6, 2024

(30) Foreign Application Priority Data
Jan. 29, 2024 (JP) 2024-011209

(51) Int. Cl. H10D 64/00; H10D 64/01; H10D 64/27; H10D 64/68

(52) U.S. Cl. CPC H10D 64/117; H10D 64/025; H10D 64/513; H10D 64/685

(57) ABSTRACT

A semiconductor device includes: a field plate electrode formed in an inner portion of a trench through a first insulating film, the trench being formed in a semiconductor substrate; and a gate electrode formed over the field plate electrode through a second insulating film. The first insulating film includes a stacked film made of a first oxide film in contact with the semiconductor substrate and a second oxide film in contact with the field plate electrode, and an inclination of an upper surface of the first insulating film changes at a boundary between the first oxide film and the second oxide film.

### CROSS-REFERENCE TO RELATED APPLICATION

The disclosure of Japanese Patent Application No. 2024-011209 filed on Jan. 29, 2024, including the specification, drawings and abstract is incorporated herein by reference in its entirety.

### BACKGROUND

The present invention relates to a semiconductor device and a method of manufacturing the semiconductor device, and particularly relates to a semiconductor device including a gate electrode and a field plate electrode in an inner portion of a trench and a method of manufacturing the semiconductor device.

A semiconductor device including a semiconductor element such as a power MOSFET (metal oxide semiconductor field effect transistor) adopts a trench gate structure in which a gate electrode is embedded in an inner portion of a trench. As one type of the trench gate structure, a split gate structure in which a field plate electrode is formed in a lower portion of a trench while a gate electrode is formed in an upper portion of the trench is known. A source potential is supplied from a source electrode to the field plate electrode. A depletion layer is spread to a drift region by the field plate electrode, thereby making it possible to increase a concentration of the drift region and to reduce a resistance of the drift region.

There is disclosed a technique listed below.
[Patent Document 1] Japanese Unexamined Patent Application Publication No. 2011-199109

For example, the Patent Document 1 discloses the MOSFET having the split gate structure. A field plate electrode and a gate electrode in the Patent Document 1 are formed as follows. First, a field plate electrode is formed in an inner portion of a trench, and an upper surface of the field plate electrode is then recessed. Then, by thermal oxidation process, a gate insulating film is formed in the inner portion of the trench while an insulating film is formed on the upper surface of the field plate electrode. Then, a gate electrode is formed on the field plate electrode to fill the inner portion of the trench.

### SUMMARY

The MOSFET having the split gate structure has a problem in which BVoss (a breakdown voltage of the MOSFET) is increased once by increase in a potential (FP potential) of the field plate electrode and then is rapidly decreased by further increase in the FP potential to exceed a certain FP potential, and thus, there is need to develop a structure with gentle decrease in the BVDss, in other words, high robustness of the BVoss in response to the increase in the FP potential. In a process for increasing the BVoss in a method of manufacturing the MOSFET having the split gate structure including the trench, the BVDss tends to deteriorate due to a process variation in many cases.

Other problems and novel characteristics will be apparent from the description of this specification and the accompanying drawings.

The outline of the typical aspects of the embodiments disclosed in the present application will be briefly described as follows.

A semiconductor device according to one embodiment includes: a semiconductor substrate having an upper surface and a lower surface; a trench formed in the semiconductor substrate to reach a predetermined depth from the upper surface of the semiconductor substrate toward the lower surface of the semiconductor substrate; a first insulating film formed from a bottom surface of the trench to a portion of a side surface of the trench; a gate insulating film connected to the first insulating film and formed on the side surface of the trench; a field plate electrode formed in an inner portion of the trench through the first insulating film; a gate electrode formed in the inner portion of the trench through the gate insulating film; and a second insulating film separating the field plate electrode and the gate electrode from each other. The first insulating film includes a stacked film made of a first oxide film in contact with the side surface of the trench and a second oxide film in contact with the field plate electrode, and an inclination of an upper surface of the first insulating film connected to the gate insulating film changes at a boundary between the first oxide film and the second oxide film.

A method of manufacturing a semiconductor device according to one embodiment includes: a step (a) of preparing a semiconductor substrate having an upper surface and a lower surface; a step (b) of forming a trench in the semiconductor substrate to reach a predetermined depth from the upper surface of the semiconductor substrate toward the lower surface of the semiconductor substrate after the step (a); a step (c) of forming a first insulating film in an inner portion of the trench and on the upper surface of the semiconductor substrate after the step (b); a step (d) of forming a field plate electrode on the first insulating film to fill the inner portion of the trench after the step (c); a step (e) of recessing the field plate electrode toward a bottom portion of the trench by etching process after the step (d); a step (f) of removing the first insulating film positioned on the upper surface of the semiconductor substrate and recessing the first insulating film positioned in the inner portion of the trench toward the bottom portion of the trench by etching process after the step (e); a step (g) of forming a gate insulating film on the upper surface of the semiconductor substrate and in the inner portion of the trench and forming a second insulating film to cover the field plate electrode exposed from the first insulating film after the step (f); and a step (h) of forming a gate electrode on the gate insulating film, on the first insulating film, and on the second insulating film to fill the inner portion of the trench after the step (g). The step (c) includes a step of forming a first oxide film in contact with the semiconductor substrate and a step of forming a second oxide film. In the step (d), the field plate electrode is formed to be in contact with the second oxide film. In the step (f), the first insulating film positioned in the inner portion of the trench is recessed toward the bottom portion of the trench such that an inclination of an upper surface of the first insulating film changes at a boundary between the first oxide film and the second oxide film.

According to one embodiment, the reliability of the semiconductor device can be improved.

### BRIEF DESCRIPTIONS OF THE DRAWINGS

FIG. 1 is a plan view illustrating a semiconductor device according to a first embodiment;

FIG. 2 is a plan view illustrating the semiconductor device according to the first embodiment;

FIG. 3 is a plan view of a principal part illustrating the semiconductor device according to the first embodiment;

FIG. 4 is a plan view of a principal part illustrating the semiconductor device according to the first embodiment;

FIG. 5 is a cross-sectional view illustrating the semiconductor device according to the first embodiment;

FIG. 6 is a schematic cross-sectional view illustrating a configuration of a first insulating film in the semiconductor device according to the first embodiment;

FIG. 7 is a schematic cross-sectional view illustrating configurations before and after etching of the first insulating film in the semiconductor device according to the first embodiment;

FIG. 8 is a diagram illustrating condition setting for performing a simulation as to how a BVoss property changes depending on a cross-sectional shape of a first oxide film included in the first insulating film;

FIG. 9 is a diagram illustrating a result of the simulation performed as to how the BVoss property changes depending on the cross-sectional shape of the first oxide film included in the first insulating film;

FIG. 10 is a cross-sectional view illustrating a step of manufacturing the semiconductor device according to the first embodiment;

FIG. 11 is a cross-sectional view illustrating a manufacturing step continued from the step illustrated in FIG. 10;

FIG. 12 is a cross-sectional view illustrating a manufacturing step continued from the step illustrated in FIG. 11;

FIG. 13 is a cross-sectional view illustrating a manufacturing step continued from the step illustrated in FIG. 12;

FIG. 14 is a cross-sectional view illustrating a manufacturing step continued from the step illustrated in FIG. 13;

FIG. 15 is a cross-sectional view illustrating a manufacturing step continued from the step illustrated in FIG. 14;

FIG. 16 is a cross-sectional view illustrating a manufacturing step continued from the step illustrated in FIG. 15;

FIG. 17 is a cross-sectional view illustrating a manufacturing step continued from the step illustrated in FIG. 16;

FIG. 18 is a cross-sectional view illustrating a manufacturing step continued from the step illustrated in FIG. 17;

FIG. 19 is a cross-sectional view illustrating a manufacturing step continued from the step illustrated in FIG. 18;

FIG. 20 is a cross-sectional view illustrating a manufacturing step continued from the step illustrated in FIG. 19;

FIG. 21 is a cross-sectional view illustrating a manufacturing step continued from the step illustrated in FIG. 20;

FIG. 22 is a cross-sectional view illustrating a manufacturing step continued from the step illustrated in FIG. 21;

FIG. 23 is a cross-sectional view illustrating a manufacturing step continued from the step illustrated in FIG. 22; and

FIG. 24 is a cross-sectional view illustrating a manufacturing step continued from the step illustrated in FIG. 23.

### DETAILED DESCRIPTION

Hereinafter, embodiments will be described in detail with reference to the accompanying drawings. Note that components having the same function are denoted by the same reference symbols throughout all the drawings for describing the embodiments, and the repetitive description thereof will be omitted. In addition, the description of the same or similar portions is not repeated in principle unless otherwise particularly required in the following embodiments.

An X-direction, a Y-direction, and a Z-direction described in the present application intersect one another and perpendicular to one another. In the present application, the Z-direction is described as an up-down direction, a height direction, or a thickness direction of a structure. An expression such as “plan view” or “planar view” used in the present application means that a surface made of the X-direction and the Y-direction is referred to as a “plane” viewed in the Z-direction.

### First Embodiment

### <Structure of Semiconductor Device>

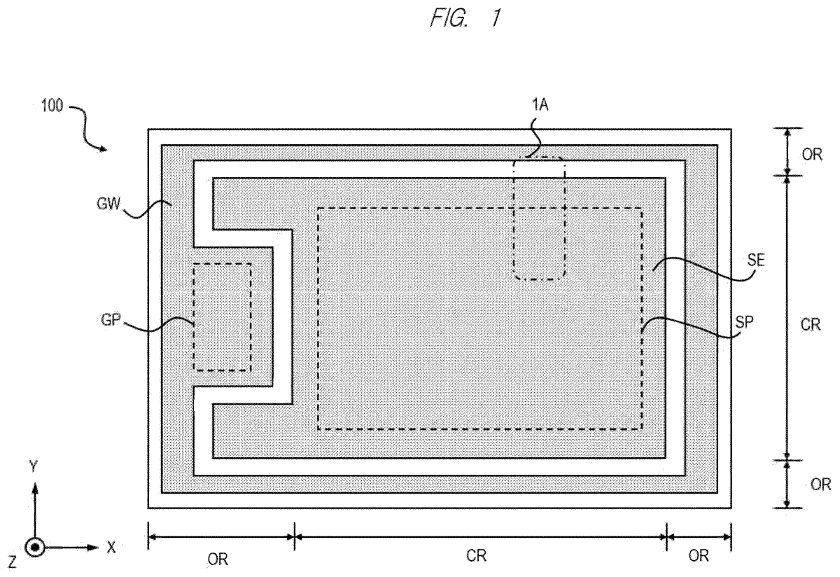

A semiconductor device 100 according to a first embodiment will be described below with reference to FIGS. 1 to 5. The semiconductor device 100 includes a MOSFET having a trench gate structure as a semiconductor element. The MOSFET in the first embodiment forms a split gate structure including a gate electrode GE and a field plate electrode FP.

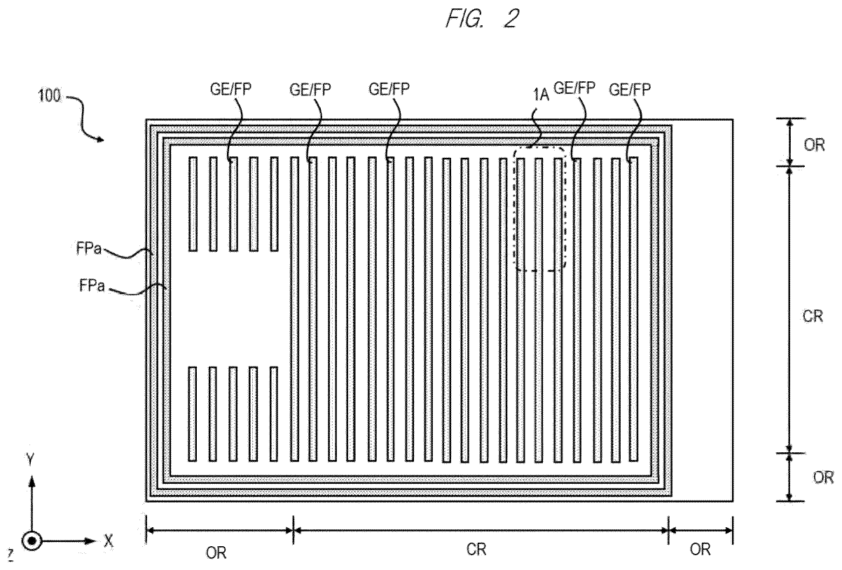

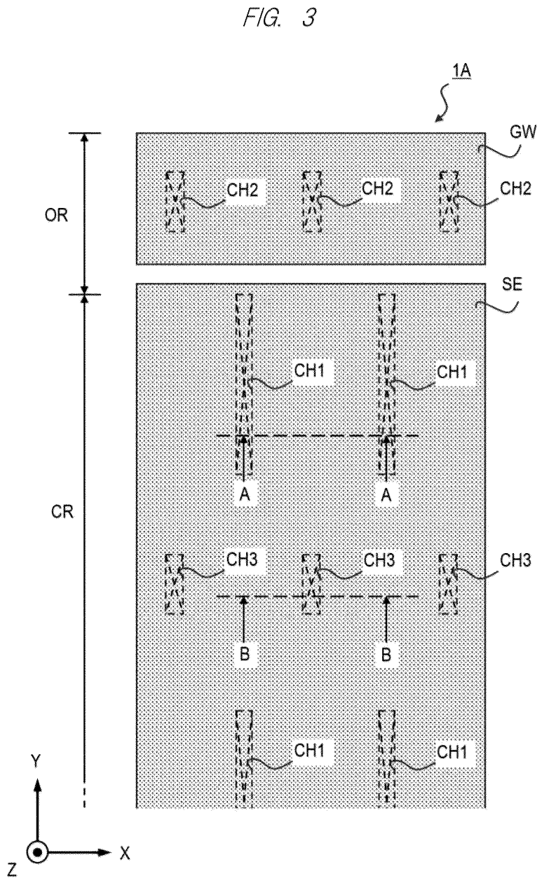

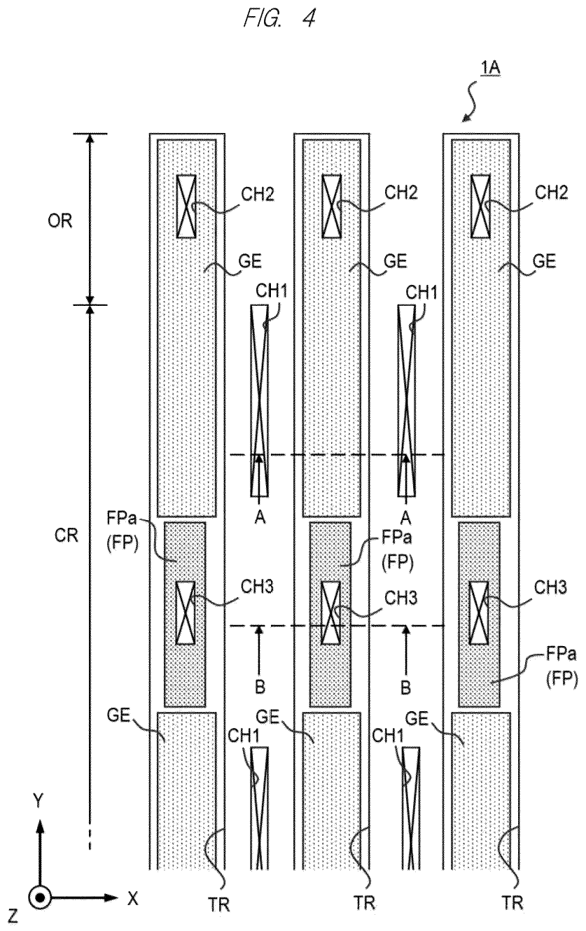

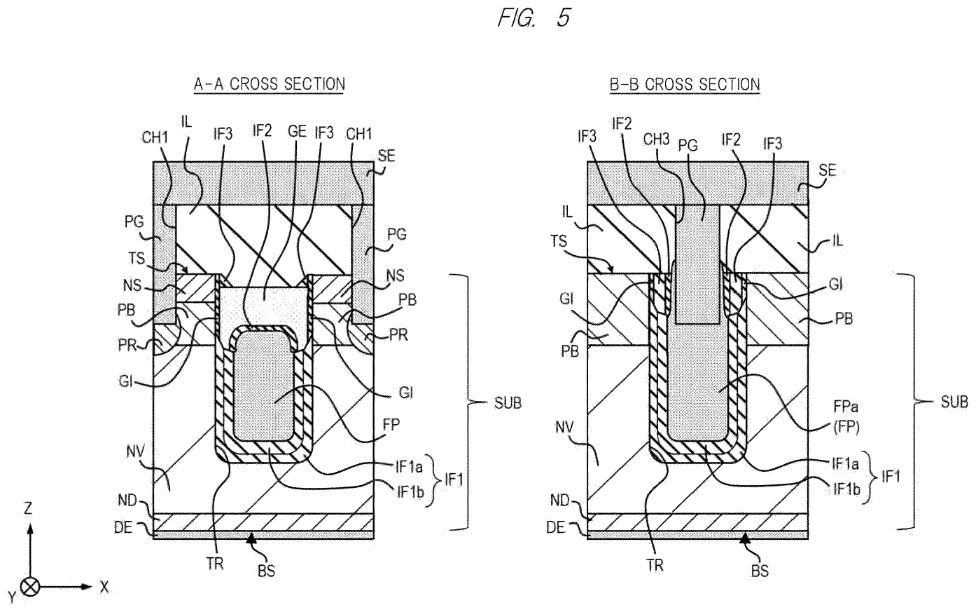

Each of FIGS. 1 and 2 is a plan view of a semiconductor chip as the semiconductor device 100. Each of FIGS. 3 and 4 is a plan view of a principal part illustrating a region 1A illustrated in FIGS. 1 and 2 to be enlarged. FIGS. 2 and 4 respectively illustrate structures below FIGS. 1 and 3, and each mainly illustrate the trench gate structure formed in the semiconductor substrate SUB. Positions of contact holes CH1, CH2, and CH3 illustrated with broken lines in FIG. 3 respectively coincide with positions of contact holes CH1, CH2, and CH3 illustrated in FIG. 4. FIG. 5 is a cross-sectional view taken along a line A-A and a line B-B illustrated in each of FIGS. 3 and 4.

FIG. 1 mainly illustrates a wiring pattern formed above the semiconductor substrate SUB. The semiconductor device 100 includes a cell region CR and an outer peripheral region OR surrounding the cell region CR in plan view. A plurality of main semiconductor elements such as MOSFETs are formed in the cell region CR. The outer peripheral region OR is used for, for example, connecting a gate wiring GW to the gate electrode GE and functioning as a termination region.

As illustrated in FIGS. 1 and 2, most of the cell region CR is covered with a source electrode SE. The gate wiring GW surrounds the source electrode SE in plan view. The source electrode SE and the gate electrode GW are covered with a protective film such polyimide film, although not illustrated. A portion of the protective film is provided with an opening, and the source electrode SE and the gate wiring GW exposed in the opening respectively serve as a source pad SP and a gate pad GP. When an external connection member is connected onto the source pad SP and the gate pad GP, the semiconductor device 100 is electrically connected to another semiconductor chip, lead frame, wiring board, or the like. The external connection member is, for example, a wire made of aluminum, gold, or copper, or a clip made of a copper plate.

As illustrated in FIG. 4, a plurality of trenches TR are formed in the semiconductor substrate SUB in the cell region CR. The plurality of trenches TR are formed in a stripe pattern, and respectively extend in the Y-direction and are adjacent to one another in the X-direction.

As also illustrated in a cross-sectional view A-A in FIG. 5, in the inner portion of the trench TR, the field plate electrode FP is formed in a lower portion of the trench TR, and the gate electrode GE is formed in an upper portion of the trench TR. The field plate electrode FP and the gate electrode GE extend along the trench TR in the Y-direction.

As also illustrated in a cross-sectional view B-B in FIG. 5, a portion of the field plate electrode FP in the cell region CR forms a pullout part FPa. The field plate electrode FP forming the pullout part FPa is formed in not only the lower portion of the trench TR but also the upper portion of the trench TR in the inner portion of the trench TR.

As illustrated in FIG. 2, the plurality of trenches TR formed in the outer peripheral region OR extend in the Y-direction and the X-direction to surround the cell region CR in plan view. The field plate electrode FP forming the pullout part FPa is formed in the inner portion of the trench TR in the outer peripheral region OR.

In the cell region CR, the contact hole CH3 is formed on the pullout part FPa. The pullout part FPa is electrically connected to the source electrode SE through the contact hole CH3. In the cell region CR, the contact hole CH1 is formed on a body region PB and a source region NS, described below. The body region PB and the source region NS are electrically connected to the source electrode SE through the contact hole CH1. In the outer peripheral region OR, the contact hole CH2 is formed on the gate electrode GE. The gate electrode GE is electrically connected to the gate wiring GW through the contact hole CH2.

A cross-sectional structure of the semiconductor device 100 will be described below with reference to FIG. 5.

As illustrated in FIG. 5, the semiconductor device 100 includes an n-type semiconductor substrate SUB having an upper surface TS and a lower surface BS. The semiconductor substrate SUB is made of n-type silicon. The semiconductor substrate SUB has an n-type drift region NV having a low concentration. In the first embodiment, the n-type semiconductor substrate SUB itself forms the drift region NV. The semiconductor substrate SUB may be a stacked body of an n-type silicon substrate and an n-type semiconductor layer grown on the n-type silicon substrate while being doped with phosphorus (P) by an epitaxial growing method. In the case, the n-type semiconductor layer having the low concentration forms the drift region NV, and the n-type silicon substrate having the high concentration forms a drain region ND. The n-type drain region ND is formed in the semiconductor substrate SUB to reach a predetermined depth from the lower surface BS of the semiconductor substrate SUB toward the upper surface TS of the semiconductor substrate SUB. The drain region ND has a higher impurity concentration than that of the drift region NV. A drain electrode DE is formed on the lower surface BS of the semiconductor substrate SUB. The drain electrode DE is made of a single-layer metal film such as an aluminum film, a titanium film, a nickel film, a gold film, or a silver film or a stacked film obtained by appropriately stacking the metal films. The drain region ND and the drain electrode DE are formed over the cell region CR and the outer peripheral region OR. To the semiconductor substrate SUB (the drain region ND and the drift region NV), a drain potential is supplied from the drain electrode DE.

The plurality of trenches TR that reach a predetermined depth from the upper surface TS of the semiconductor substrate SUB toward the lower surface BS of the semiconductor substrate SUB are formed in the semiconductor substrate SUB.

As illustrated in the cross section A-A in FIG. 5, in the inner portion of the trench TR, the field plate electrode FP is formed in the lower portion of the trench TR through a first insulating film IF1. A position of an upper surface of the first insulating film IF1 is lower than a position of the upper surface of the field plate electrode FP.

The first insulating film IF1 includes a first oxide film IF1a in contact with the semiconductor substrate SUB and a second oxide film IF1b in contact with the field plate electrode FP. An inclination of the upper surface of the first insulating film IF1 in a cross-sectional view changes at a boundary between the first oxide film IF1a and the second oxide film IF1b. In one example, each of an upper surface of the first oxide film IF1a and an upper surface of the second oxide film IF1b has a shape that more ascends as being closer from the field plate electrode FP toward the semiconductor substrate SUB in a cross-sectional view as illustrated in FIG. 5, and an ascensional rate of the ascension of the upper surface of the first oxide film IF1a in the cross-sectional view is higher than an ascensional rate of the ascension of the upper surface of the second oxide film IF1b in the cross-sectional view. Note that the upper surface of the second oxide film IF1b may not have the shape that more ascends as being closer from the field plate electrode FP toward the semiconductor substrate SUB, and may be, for example, flat. The change in the inclination described herein may be a change in curvature.

A gate insulating film GI is formed in the inner portion of the trench TR on the insulating film IF1. A second insulating film IF2 is formed to cover the field plate electrode FP exposed from the first insulating film IF1. The gate electrode GE is formed over the field plate electrode FP through the second insulating film IF2. The field plate electrode FP and the gate electrode GE are each made of, for example, a polycrystal silicon film doped with an n-type impurity. The impurity concentration of the polycrystal silicon film is higher than the impurity concentration of the semiconductor substrate SUB (the drift region NV).

A portion of the gate electrode GE is also formed in a space between the field plate electrode FP and the semiconductor substrate SUB and surrounded by the first insulating film IF1, the second insulating film IF2, and the gate insulating film GI.

The first insulating film IF1 is formed between the semiconductor substrate SUB and the field plate electrode FP. The second insulating film IF2 is formed between the gate electrode GE and the field plate electrode FP. The gate insulating film GI is formed between the semiconductor substrate SUB and the gate electrode GE. The semiconductor substrate SUB, the gate electrode GE, and the field plate electrode FP are electrically insulated from one another by the films.

An etching rate of the second oxide film IF1b is higher than an etching rate of the first oxide film IF1a in the first insulating film IF1 for a predetermined etchant such as a BHF (buffered hydrofluoric acid), a DHF (dilute hydrofluoric acid), or a gas phase hydrofluoric acid. In one example, the first oxide film IF1a is made of a dry oxide film (silicon oxide film) formed by thermal oxidation process for a silicon substrate, and the second oxide film IF1b is made of an LPCVD-TEOS film formed by depositing a silicon oxide film by an LPCVD (low-pressure chemical vapor deposition) apparatus using TEOS (tetra ethoxy silane) as a raw material on the first oxide film IF1a. The second insulating film IF2 and the gate insulating film GI are each made of, for example, a silicon oxide film.

The p-type body region PB that reaches a predetermined depth from the upper surface TS of the semiconductor substrate SUB toward the lower surface BS of the semiconductor substrate SUB is formed in the semiconductor substrate SUB. The depth of the body region PB from the upper surface TS of the semiconductor substrate SUB is shallower than the depth of the trench TR from the upper surface TS of the semiconductor substrate SUB. The n-type source region NS is formed in the body region PB. The source region NS has a higher impurity concentration than that of the drift region NV.

An interlayer insulating film IL is formed on the upper surface TS of the semiconductor substrate SUB to cover the trench TR. The interlayer insulating film IL is made of, for example, a silicon oxide film.

The contact hole CH1 that penetrates the interlayer insulating film IL and the source region NS and reaches the body region PB is formed in the interlayer insulating film IL. A high-concentration diffusion region PR is formed in the body region PB in a bottom portion of the contact hole CH1. The high-concentration diffusion region PR has a higher impurity concentration than that of the body region PB. The high-concentration diffusion region PR is mainly provided to reduce a contact resistance with a plug PG and to prevent latch-up.

The source electrode SE is formed on the interlayer insulating film IL. The source electrode SE is electrically connected to the source region NS, the body region PB, and the high-concentration diffusion region PR through the contact hole CH1, and supplies a source potential to these impurity regions.

As illustrated in the cross section B-B in FIG. 5, a portion of the field plate electrode FP forms the pullout part FPa in the field plate electrode FP. A position on the upper surface of the first insulating film IF1 being in contact with the pullout part FPa is higher than a position on the upper surface of the first insulating film IF1 being in contact with the field plate electrode FP other than the pullout part FPa.

The second insulating film IF2 is formed to cover the pullout part FPa exposed from the first insulating film IF1. Although the body region PB is formed in the semiconductor substrate SUB adjacent to the pullout part FPa, the source region NS is not formed in this body region PB.

The contact hole CH3 that penetrates the interlayer insulating film IL and reaches the pullout part FPa is formed in the interlayer insulating film IL. The source electrode SE is electrically connected to the pullout part FPa through the contact hole CH3, and supplies a source potential to the field plate electrode FP.

The contact hole CH2 that penetrates the interlayer insulating film IL and reaches the gate electrode GE is formed in the interlayer insulating film IL, although not illustrated here. The gate wiring GW is electrically connected to the gate electrode GE through the contact hole CH2, and supplies a gate potential to the gate electrode GE.

The plug PG is embedded in each of the contact holes CH1, CH2, and CH3. The plug PG is made of, for example, a first barrier metal film and a first conductive film formed on the first barrier metal film. The first barrier metal film is made of, for example, a stacked film of a titanium film and a titanium nitride film. The first conductive film is, for example, tungsten film.

Each of the source electrode SE and the gate wiring GW is made of, for example, a second barrier metal film and a second conductive film formed on the second barrier metal film. The second barrier metal film is, for example, a titanium tungsten film. The second conductive film is, for example, an aluminum alloy film to which copper or silicon is added.

### Features of First Embodiment

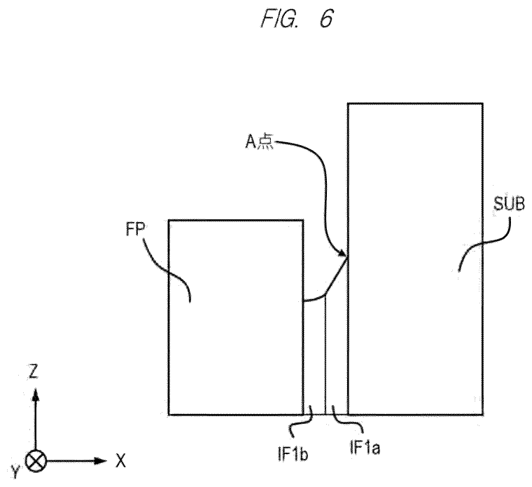

FIG. 6 is a schematic cross-sectional view illustrating a configuration of the first insulating film IF1 in the semiconductor device 100 according to the first embodiment. Since the upper surface of the first oxide film IF1a included in the first insulating film IF1 is inclined, an electric field in vicinity of a point “A” at an end of the upper surface of the first oxide film IF1a, the end being close to the semiconductor substrate SUB side, is moderated, and it is considerable that the robustness of BVoss is improved.

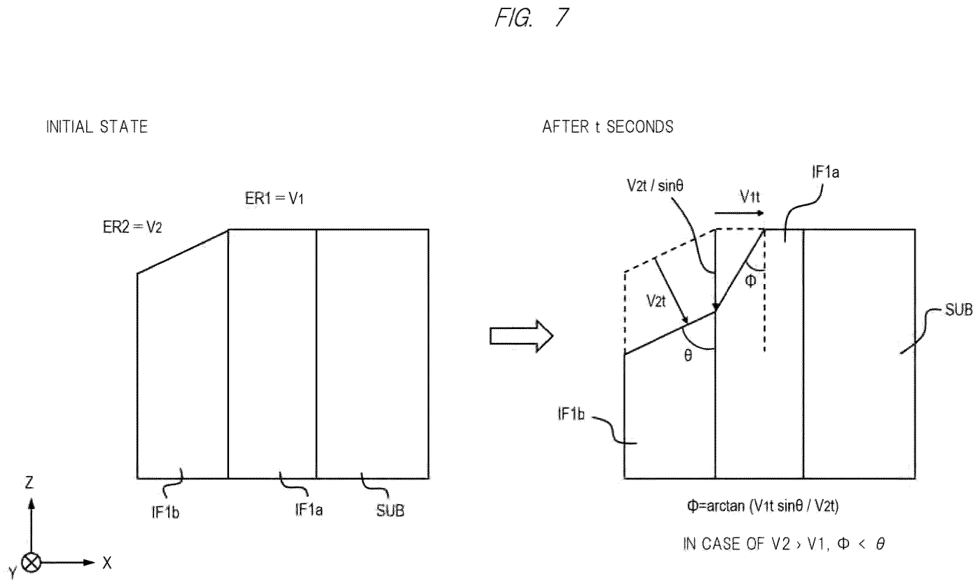

FIG. 7 is a schematic cross-sectional view illustrating configurations before and after etching of the first insulating film IF1 in the semiconductor device 100 according to the first embodiment. When it is assumed that the first oxide film IF1a has an etching rate “ER1=V₁” (micrometers per second) while the second oxide film IF1b has an etching rate “ER2=V₂” (micrometers per second), a relationship “φ<θ” is established in a relationship “V₂>V₁” after etching process for “t” seconds. By such configurations, the electric field in the vicinity of the point A illustrated in FIG. 6 is moderated as described above. As such a combination of the etchant, the first oxide film IF1a, and the second oxide film IF1b as to satisfy V₂>V₁, a combination using any one of the BHF, the DHF, and the gas phase hydrofluoric acid as the etchant, using the dry oxide film as the first oxide film IF1a, and using the LPCVD-TEOS film as the second oxide film IF1b is exemplified. However, the present invention is not limited to this combination, and the first oxide film IFla may be, for example, a wet oxide film or the like.

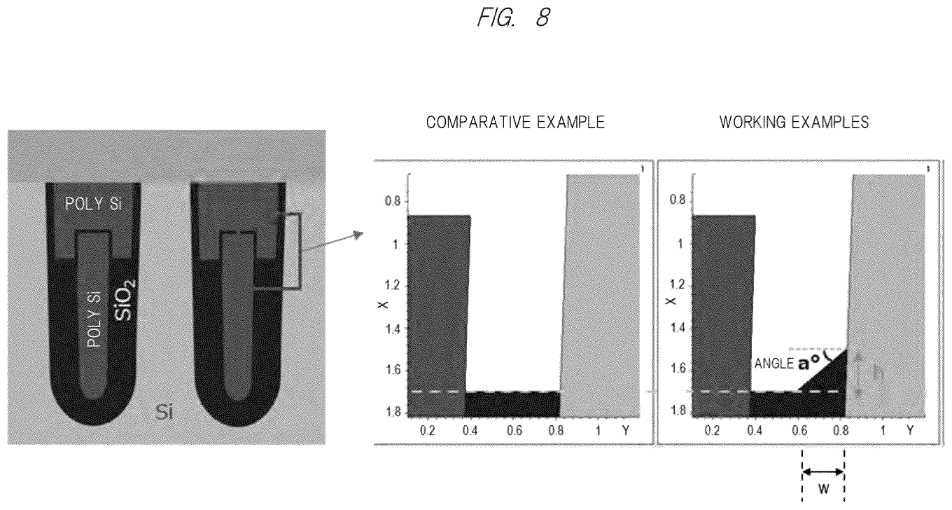

FIG. 8 is a diagram illustrating condition setting for performing a simulation as to how the BVoss property changes depending on the cross-sectional shape of the first oxide film IF1a included in the first insulating film IF1 (the X-direction in FIG. 8 corresponds to the Z-direction in FIG. 5 while the Y-direction in FIG. 8 corresponds to the X-direction in FIG. 5).

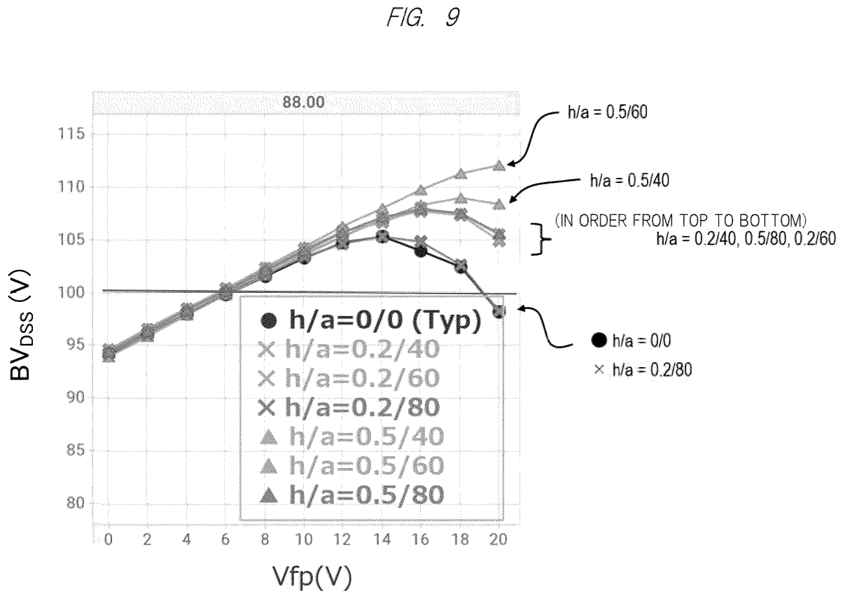

A simulation for evaluating the robustness of BVoss is performed by calculating a change in BVDss in response to a change in a field plate potential Vfp (V) while changing an angle “a” (degree) and a height “h” (arbitrary unit) of the upper surface of the first oxide film IF1a. FIG. 9 is a diagram illustrating a result of the simulation as to how the BVoss property changes depending on the cross-sectional shape of the first oxide film IF1a included in the first insulating film IF1. In a graph illustrated in FIG. 9, a horizontal axis represents the field plate potential Vfp (V), and a vertical axis represents BVDss (V). From the result of the simulation, it can be understood that the angle a is preferably 40 degrees or more and 60 degrees or less. Note that the upper surface of the first oxide film IF1a to be actually formed is not necessarily be linear as illustrated in FIG. 8 in the cross-sectional view. However, even in a case where the upper surface of the first oxide film IF1a is curved in the cross-sectional view, an average ascensional angle (which can be represented as “arctan (h/w)” using a width “w” of the first oxide film and the height “h” of the first oxide film in FIG. 8) of the ascension of the upper surface of the first oxide film IF1a in the cross-sectional view is preferably 40 degrees or more and 60 degrees or less.

### <Method of Manufacturing Semiconductor Device>

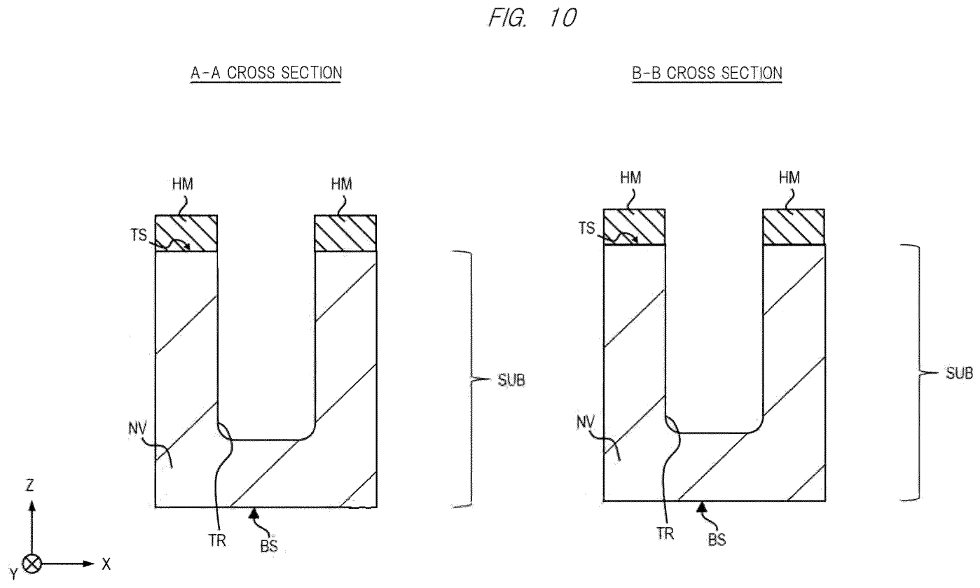

Manufacturing steps included in the method of manufacturing the semiconductor device 100 will be described below with reference to FIGS. 10 to 24.

As illustrated in FIG. 10, the n-type semiconductor substrate SUB having the upper surface TS and the lower surface BS is first prepared. As described above, the semiconductor substrate SUB may be a stacked body of the n-type silicon substrate and the n-type semiconductor layer formed on the silicon substrate by the epitaxial growing method.

Then, for example, the silicon oxide film is formed on the semiconductor substrate SUB by, for example, film formation process using a CVD (chemical vapor deposition) method. Then, the silicon oxide film is patterned to form a hard mask HM by a photolithography technique and anisotropic etching process. Then, anisotropic etching process is performed while using the hard mask HM as a mask to form the trench TR in the semiconductor substrate SUB to reach a predetermined depth from the upper surface TS of the semiconductor substrate SUB toward the lower surface BS of the semiconductor substrate SUB. Then, the hard mask HM is removed by, for example, isotropic etching process using a solution containing hydrofluoric acid.

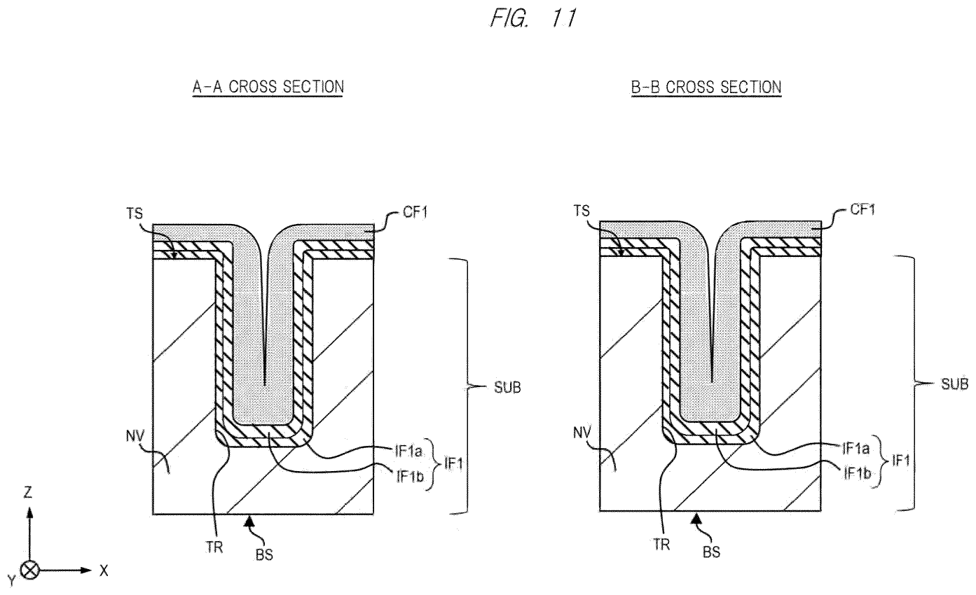

As illustrated in FIG. 11, the first insulating film IF1 including the first oxide film IF1a and the second oxide film IF1b is first formed in the inner portion of the trench TR and on the upper surface TS of the semiconductor substrate SUB. The first oxide film IF1a is, for example, a dry oxide film (silicon oxide film) formed by thermal oxidation process. The second oxide film IF1b is, for example, the LPCVD-TEOS film formed by stacking a silicon oxide film on the first oxide film IF1a while using the TEOS (tetra ethoxy silane) as a raw material by the LPCVD (low-pressure chemical vapor deposition) apparatus.

Then, the conductive film CF1 is formed on the first insulating film IF1 by, for example, film formation process using a CVD method. The conductive film CF1 is, for example, an n-type polycrystal silicon film.

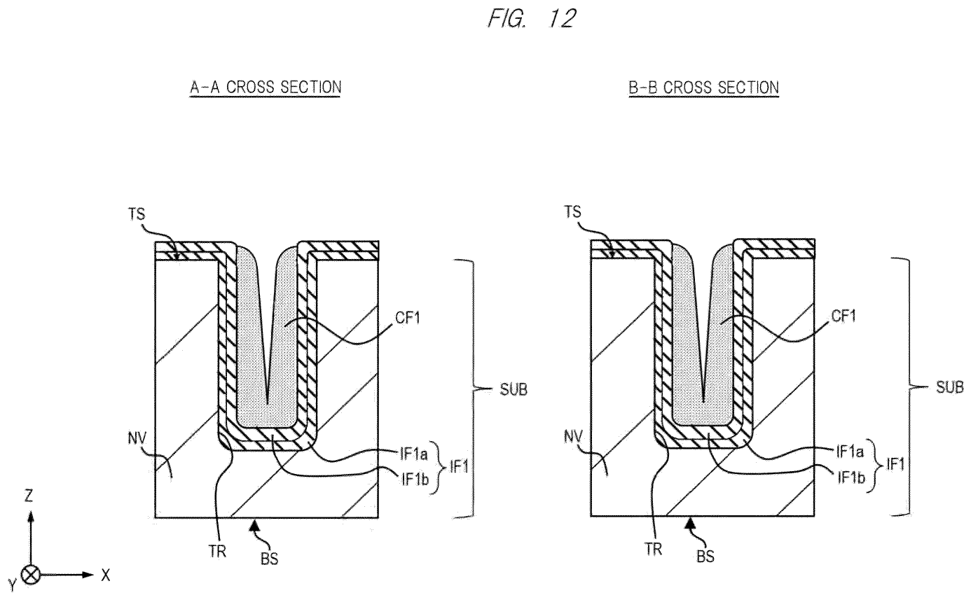

As illustrated in FIG. 12, by etching process, the thickness of the conductive film CF1 positioned in the inner portion of the trench TR is reduced, and the conductive film CF1 positioned in the outer portion of the trench TR is removed.

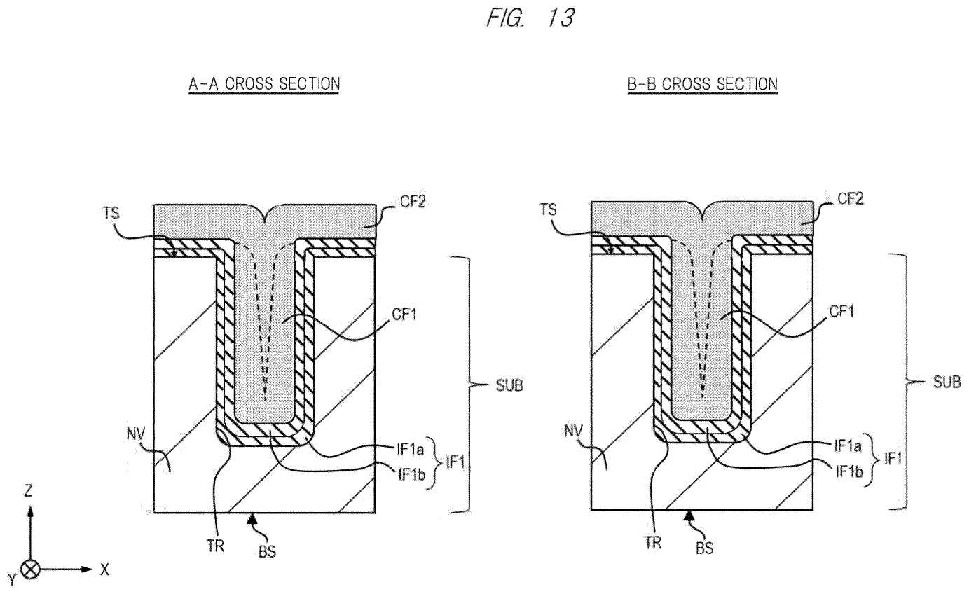

As illustrated in FIG. 13, the conductive film CF2 is formed on the first insulating film IF1 and on the conductive film CF1 to fill the inner portion of the trench TR by, for example, film formation process using a CVD method. The conductive film CF2 is also formed on the first insulating film IF1 in the outer portion of the trench TR. The conductive film CF2 is, for example, an n-type polycrystal silicon film. In the manufacturing step illustrated in FIG. 12, the thickness of the conductive film CF1 is made smaller as being closer to the uppermost portion of the trench TR. Accordingly, the conductive film CF2 can be formed in a state with a lower aspect ratio than that of a case without the conductive film CF1. Therefore, the inner portion of the trench TR is easily favorably filled with the conductive film CF2.

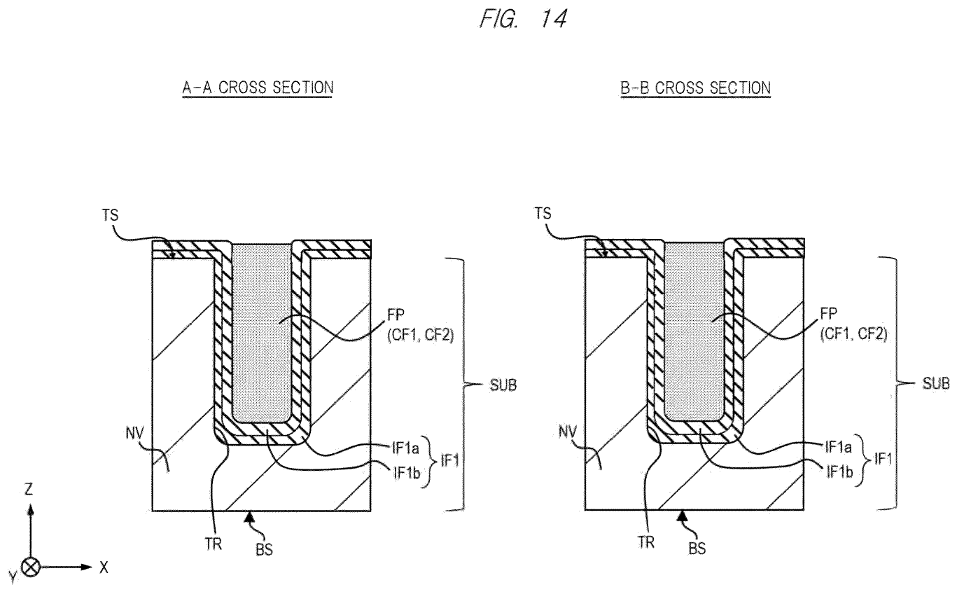

As illustrated in FIG. 14, the conductive film CF2 positioned in the outer portion of the trench TR is removed such that the conductive film CF1 and the conductive film CF2 are left in the inner portion of the trench TR by, for example, polishing process using a CMP (chemical mechanical polishing) method. The conductive film CF1 and the conductive film CF2 that are left in the inner portion of the trench TR form the field plate electrode FP. Thus, the field plate electrode FP is formed on the first insulating film IF1 to fill the inner portion of the trench TR.

Note that the field plate electrode FP can also be made of only the conductive film CF2. In the case, the conductive film CF1 is not formed while the conductive film CF2 is formed on the first insulating film IF1 to fill the inner portion of the trench TR. The conductive film CF2 positioned in the outer portion of the trench TR is removed such that the conductive film CF2 is left in the inner portion of the trench TR. The conductive film CF2 left in the inner portion of the trench TR forms the field plate electrode FP. This case can make the manufacturing steps simpler than those in the case where the field plate electrode FP is made of the conductive film CF1 and the conductive film CF2.

However, the conductive film CF1 previously processed in a sidewall shape is preferably formed in the inner portion of the trench TR, as described in FIGS. 12 to 14, from the viewpoint of favorably filling the inner portion of the trench TR with the conductive film CF2.

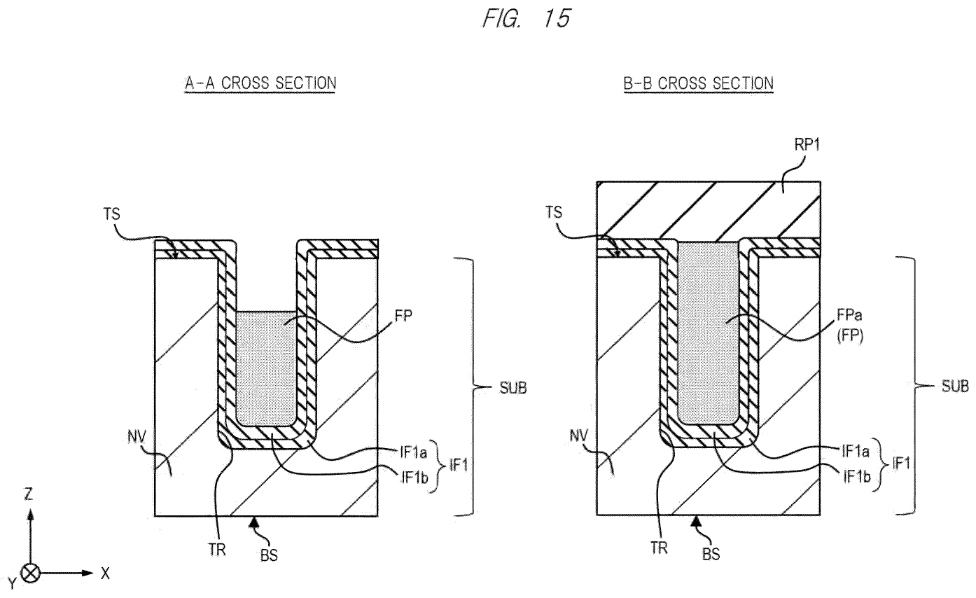

As illustrated in FIG. 15, the other portion of the field plate electrode FP is selectively recessed such that a portion of the field plate electrode FP is left as the pullout part FPa.

Specifically, a resist pattern RP1 that selectively covers a portion of the field plate electrode FP serving as the pullout part FPa is formed, as illustrated in a cross-sectional view B-B in FIG. 15. Then, etching process (etch-back process) such as dry etching or plasma etching using, for example, SF6 gas is performed to the other portion of the field plate electrode FP not serving as the pullout part FPa while using the resist pattern RP1 as a mask. That is, the other portion of the field plate electrode FP exposed from the resist pattern RP1 is selectively recessed toward a bottom portion of the trench TR, as illustrated in a cross-sectional view A-A in FIG. 15. The portion of the field plate electrode FP that has not been recessed serves as the pullout part FPa.

Although not illustrated, an upper portion of the field plate electrode FP is rounded by the etching process (planarizing process) and the thermal oxidation process to the upper surface of the field plate electrode FP.

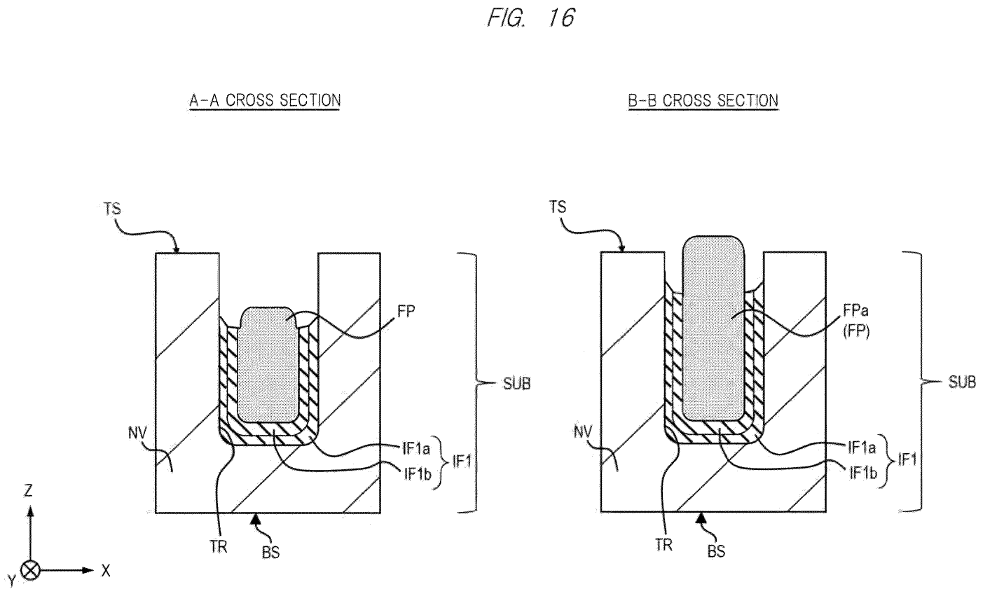

As illustrated in FIG. 16, in one example, the first insulating film IF1 positioned on the upper surface TS of the semiconductor substrate SUB is removed by isotropic etching process using a solution containing a hydrofluoric acid. At the same time, the first insulating film IF1 positioned in the inner portion of the trench TR is recessed toward the bottom portion of the trench TR such that a position of an upper surface of the first insulating film IF1 positioned in the inner portion of the trench TR is lower than a position of the upper surface of the field plate electrode FP in a cross-sectional view. The inclined structure of the upper surface of the first oxide film IF1a as illustrated in FIG. 16 is formed by the selection of such combination of the etchant, the first oxide film IF1a and the second oxide film IF1b as satisfying the conditions explained with reference to FIG. 7. At the end of the isotropic etching process, the upper surface of the first insulating film IF1 has a shape that more ascends as being closer to the semiconductor substrate SUB.

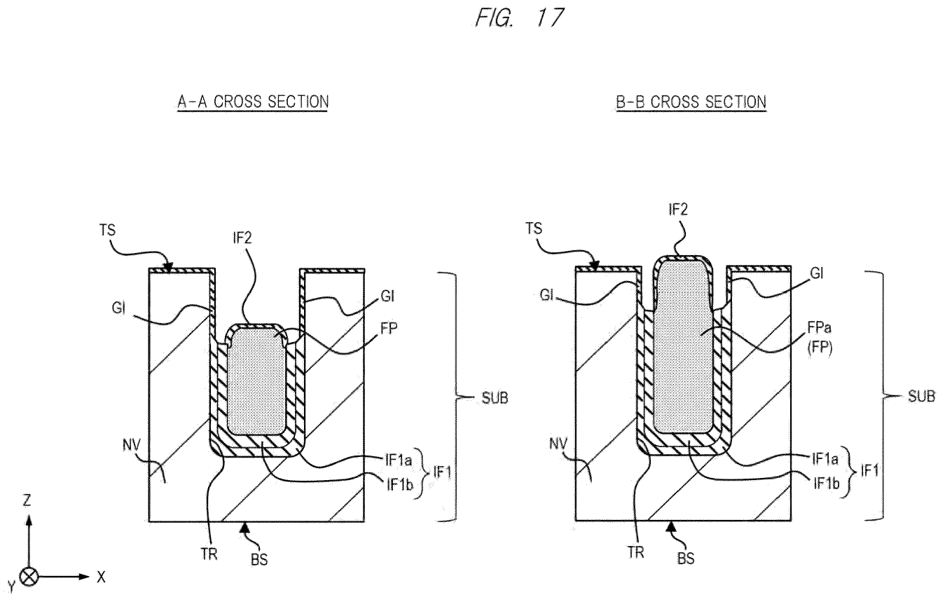

As illustrated in FIG. 17, by thermal oxidation process, the gate insulating film GI is formed on the upper surface TS of the semiconductor substrate SUB and in the inner portion of the trench TR positioned on the first insulating film IF1 while the second insulating film IF2 is formed to cover the field plate electrode FP exposed from the first insulating film IF1.

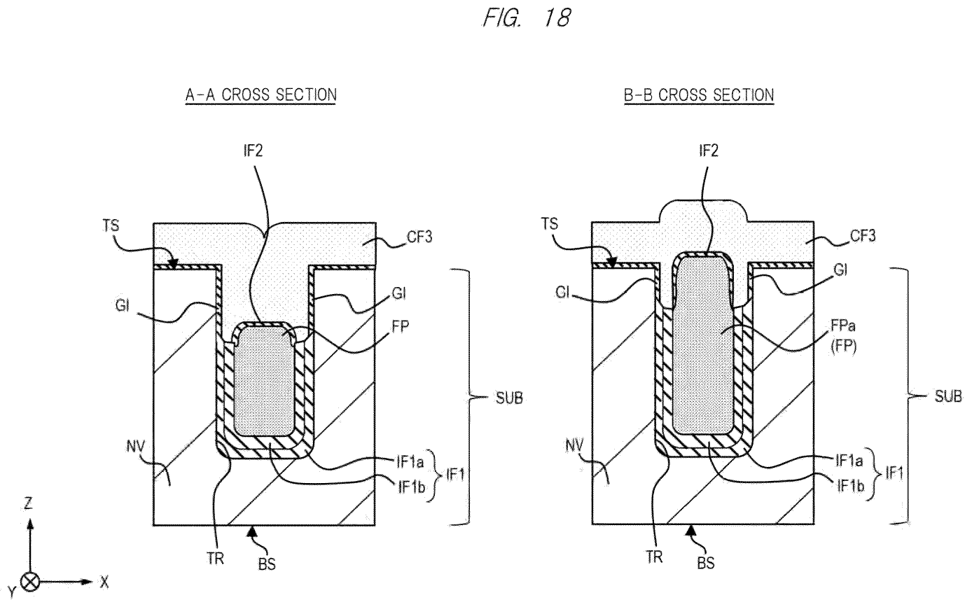

As illustrated in FIG. 18, the conductive film CF3 is formed on the gate insulating film GI, on the second insulating film IF2, and on the first insulating film IF1 to fill the inner portion of the trench TR by, for example, film formation process using a CVD method. The conductive film CF3 is, for example, an n-type polycrystal silicon film.

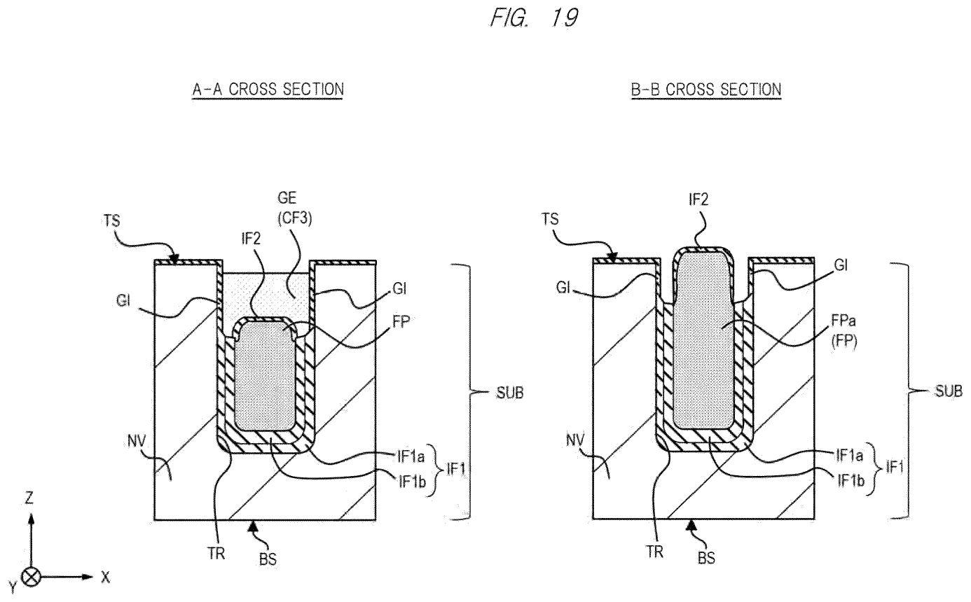

As illustrated in FIG. 19, first, polishing process using a CMP method is performed to the conductive film CF3. As a result, the thickness of the conductive film CF3 is reduced, and an upper surface of the conductive film CF3 is planarized. Then, anisotropic etching process is performed to the conductive film CF3 to remove the conductive film CF3 positioned in the outer portion of the trench TR. As a result, the conductive film CF3 left in the inner portion of the trench TR on the field plate electrode FP is formed as the gate electrode GE, as illustrated in a cross-sectional view A-A in FIG. 19.

In order to completely remove the conductive film CF3 positioned in the outer portion of the trench TR, overetching is performed for the anisotropic etching process. Accordingly, a position of an upper surface of the gate electrode GE is lower than the position of the upper surface TS of the semiconductor substrate SUB, as illustrated in the cross-sectional view A-A in FIG. 19. The conductive film CF3 formed on the second insulating film IF2 and on the first insulating film IF1 being in contact with the pullout part FPa is removed by the anisotropic etching process, as illustrated in a cross-sectional view B-B in FIG. 19.

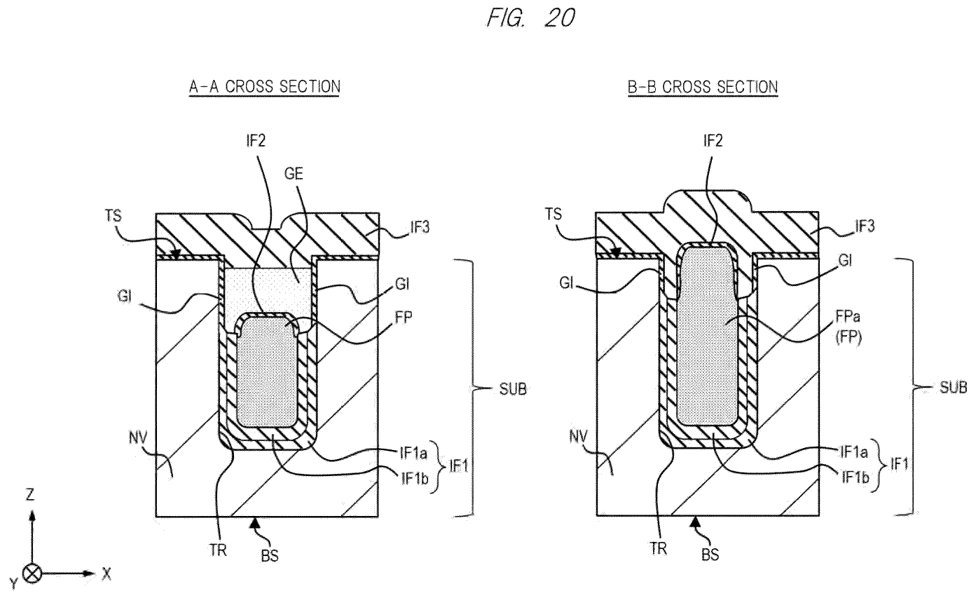

As illustrated in FIG. 20, a third insulating film IF3 is formed on the gate insulating film GI, on the gate electrode GE, on the second insulating film IF2, and on the first insulating film IF1 to cover the trench TR by, for example, film formation process using a CVD method.

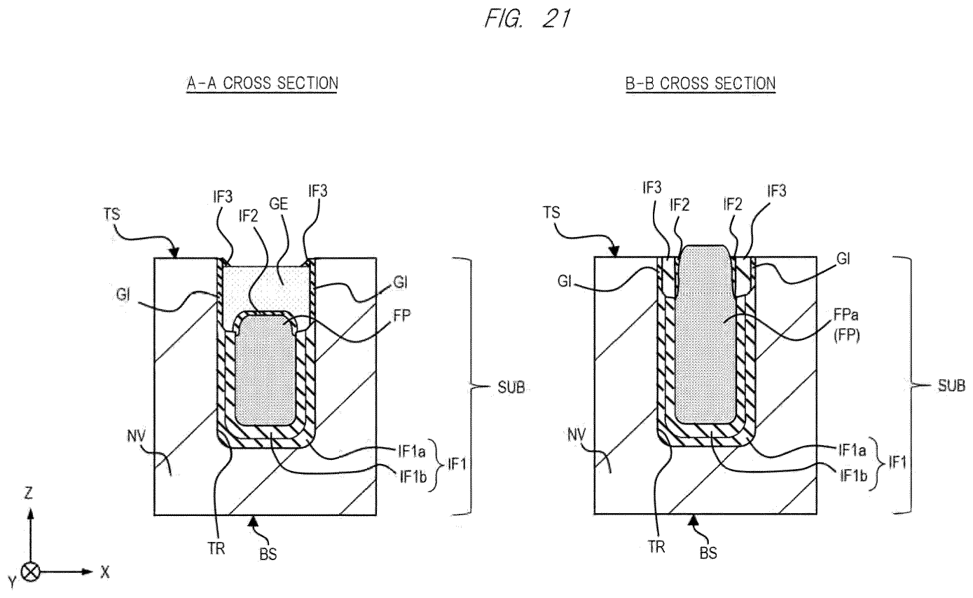

As illustrated in FIG. 21, anisotropic etching process is performed to the third insulating film IF3. As a result, the third insulating film IF3 and the gate insulating film GI on the upper surface TS of the semiconductor substrate SUB and the second insulating film IF2 on the field plate electrode FP are removed. The third insulating film IF3 is left on a portion of the gate electrode GE and on the first insulating film IF1 being in contact with the pullout part FPa, as illustrated in FIG. 21.

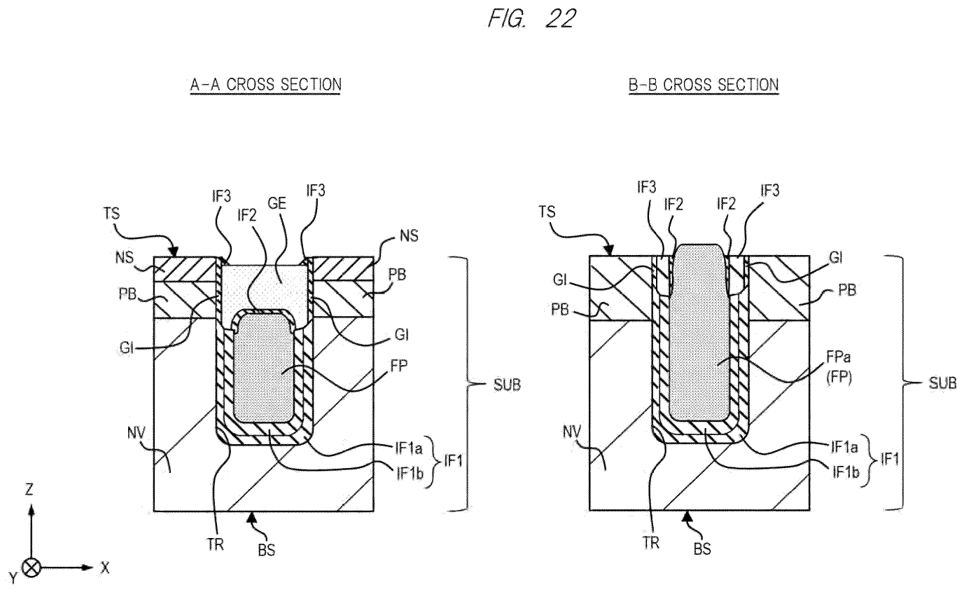

As illustrated in FIG. 22, first, the p-type body region PB is selectively formed in the semiconductor substrate SUB by a photolithography technique and an ion implantation method for doping with an impurity such as boron (B). The body region PB is formed such that the depth itself from the upper surface TS of the semiconductor substrate SUB is shallower than the depth of the trench TR.

Then, the n-type source region NS is selectively formed in the body region PB in the cell region CR by a photolithography technique and an ion implantation method for doping with an impurity such as arsenic (As), as illustrated in a cross-sectional view A-A in FIG. 22. The source region NS is not formed in the body region PB adjacent to the pullout part FPa, as illustrated in a cross-sectional view B-B in FIG. 22. Then, heat process is performed to the semiconductor substrate SUB to activate the impurities contained in the source region NS and the body region PB.

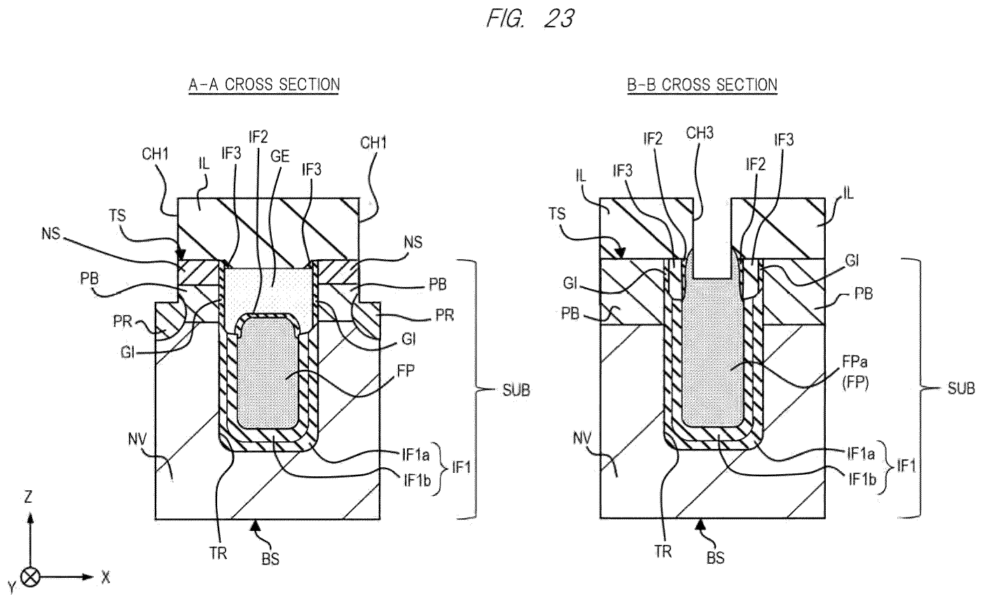

As illustrated in FIG. 23, first, the interlayer insulating film IL is formed on the upper surface TS of the semiconductor substrate SUB to cover the trench TR by, for example, a CVD method.

Then, the contact holes CH1, CH2, and CH3 are formed in the interlayer insulating film IL. Specifically, first, a resist pattern having a pattern for opening the upper portion of the source region NS is formed on the interlayer insulating film IL. Then, anisotropic etching process is performed while using the resist pattern as a mask to form the contact hole CH1 that penetrates the interlayer insulating film IL and the source region NS and reaches the inside of the body region PB. Then, the body region PB in the bottom portion of the contact hole CH1 is doped with the impurity such as boron (B) by an ion implantation method to form the p-type high-concentration diffusion region PR. Then, the resist pattern is removed by ashing process.

Then, a resist pattern having a pattern for opening the upper portion of the pullout part FPa and the upper portion of the gate electrode GE is formed on the interlayer insulating film IL. Then, anisotropic etching process is performed while using the resist pattern as a mask to form the contact hole CH3 that penetrates the interlayer insulating film IL and reaches the pullout part FPa. The contact hole CH2 is also formed by the manufacturing step of forming the contact hole CH3, although not illustrated here. The contact hole CH2 penetrates the interlayer insulating film IL and reaches the gate electrode GE. Then, the resist pattern is removed by ashing process.

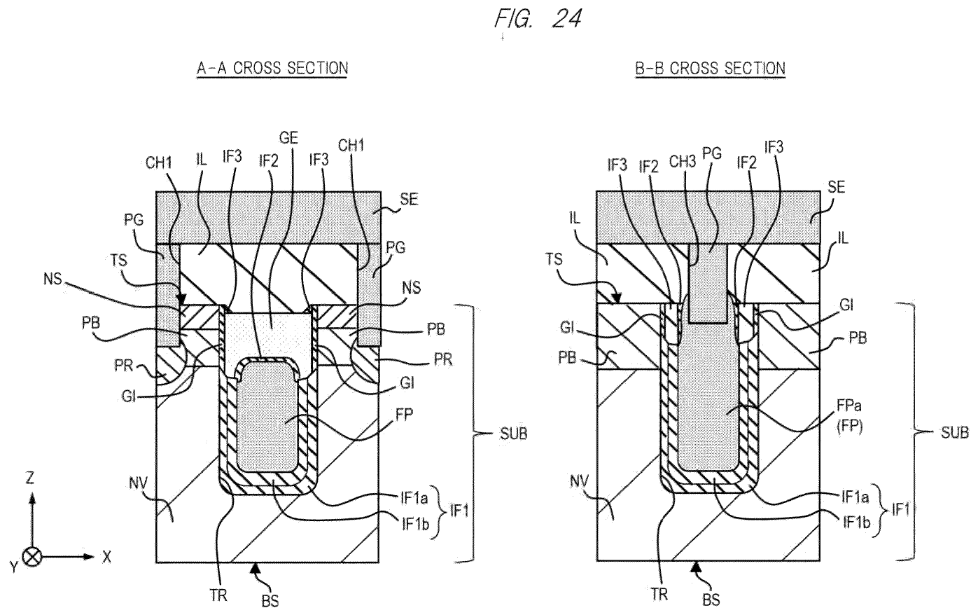

As illustrated in FIG. 24, the plug PG is formed in each of the contact holes CH1, CH2, and CH3, and the source electrode SE and the gate wiring GW are formed on the interlayer insulating film IL.

First, the first barrier metal film is formed in each of the contact holes CH1, CH2, and CH3 and on the interlayer insulating film IL by film formation process using a sputtering method or a CVD method. The first barrier metal film is made of, for example, a stacked film of a titanium nitride film and a titanium film. Then, the first conductive film is formed on the first barrier metal film by film formation process using a CVD method. The first conductive film is made of, for example, a tungsten film. Then, the first barrier metal film and the first conductive film in the outer portion of each of the contact holes CH1, CH2, and CH3 are removed by polishing process using a CMP method or anisotropic etching process. As a result, the plug PG made of the first barrier metal film and the first conductive film is formed to fill the inner portion of each of the contact holes CH1, CH2, and CH3.

Then, the second barrier metal film is formed on the interlayer insulating film IL by film formation process using a sputtering method. The second barrier metal film is made of, for example, a titanium tungsten film. Then, the second conductive film is formed on the second barrier metal film by film formation process using a sputtering method. The second conductive film is, for example, an aluminum alloy film to which copper or silicon is added. Then, the second barrier metal film and the second conductive film are patterned to form the source electrode SE and the gate wiring GW.

Then, the protective film made of, for example, a polyimide film is formed on the source electrode SE and the gate wiring GW by, for example, a coating method, although not illustrated here. The opening is formed in a portion of the protective film to expose respective regions of the source electrode SE and the gate wiring GW, the regions serving as the source pad SP and the gate pad GP.

Then, the structure illustrated in FIG. 5 is obtained through the following manufacturing steps. First, the lower surface BS of the semiconductor substrate SUB is polished, as needed. Then, the lower surface BS of the semiconductor substrate SUB is doped with, for example, arsenic (As) by an ion implantation method to form the n-type drain region ND. When the semiconductor substrate SUB is made of the stacked body of the n-type silicon substrate and the n-type semiconductor layer, the n-type silicon substrate having the high concentration serves as the drain region ND. Accordingly, formation of the drain region ND by the ion implantation as described above can be omitted. Then, the drain electrode DE is formed on the lower surface BS of the semiconductor substrate SUB by film formation process using a sputtering method.

In the foregoing, the present invention has been concretely described on the basis of the embodiments. However, the present invention is not limited to the foregoing embodiments, and various modifications can be made within the scope of the present invention. The present specification describes, for example, the following configurations.

### APPENDIXES

### First Appendix

A semiconductor device includes: a semiconductor substrate having an upper surface and a lower surface; a trench formed in the semiconductor substrate to reach a predetermined depth from the upper surface of the semiconductor substrate toward the lower surface of the semiconductor substrate; a first insulating film formed from a bottom surface of the trench to a portion of a side surface of the trench; a gate insulating film connected to the first insulating film and formed on a side surface of the trench; a field plate electrode formed in an inner portion of the trench through the first insulating film; a gate electrode formed in the inner portion of the trench through the gate insulating film; and a second insulating film separating the field plate electrode and the gate electrode from each other. The first insulating film includes a stacked film made of a first oxide film in contact with the side surface of the trench and a second oxide film in contact with the field plate electrode, and an inclination of an upper surface of the first insulating film connected to the gate insulating film changes at a boundary between the first oxide film and the second oxide film.

### Second Appendix

In the semiconductor device according to the first appendix, each of an upper surface of the first oxide film and an upper surface of the second oxide film has a shape that more ascends as being closer from the field plate electrode toward the semiconductor substrate in a cross-sectional view, and an ascensional rate of the ascension of the upper surface of the first oxide film in the cross-sectional view is higher than an ascensional rate of the ascension of the upper surface of the second oxide film in the cross-sectional view.

### Third Appendix

In the semiconductor device according to the second appendix, an etching rate of the second oxide film for a predetermined etchant is higher than an etching rate of the first oxide film for the predetermined etchant.

### Fourth Appendix

In the semiconductor device according to the third appendix, the predetermined etchant contains any one of a BHF (buffered hydrofluoric acid), a DHF (dilute hydrofluoric acid), and a gas phase hydrofluoric acid.

### Fifth Appendix

In the semiconductor device according to the fourth appendix, the first oxide film is a dry oxide film, and the second oxide film is an LPCVD (low-pressure chemical vapor deposition)-TEOS (tetra ethoxy silane) film.

### Sixth Appendix

In the semiconductor device according to the second appendix, an average ascensional angle of the ascension of the upper surface of the first oxide film in the cross-sectional view is 40 degrees or more and 60 degrees or less.

### Seventh Appendix

A method of manufacturing a semiconductor device includes steps of: (a) preparing a semiconductor substrate having an upper surface and a lower surface; (b) forming a trench in the semiconductor substrate to reach a predetermined depth from the upper surface of the semiconductor substrate toward the lower surface of the semiconductor substrate after the step (a); (c) forming a first insulating film in an inner portion of the trench and on the upper surface of the semiconductor substrate after the step (b); (d) forming a field plate electrode on the first insulating film to fill the inner portion of the trench after the step (c); (e) recessing the field plate electrode toward a bottom portion of the trench by etching process after the step (d); (f) removing the first insulating film positioned on the upper surface of the semiconductor substrate and recessing the first insulating film positioned in the inner portion of the trench toward the bottom portion of the trench by etching process after the step (e); (g) forming a gate insulating film on the upper surface of the semiconductor substrate and in the inner portion of the trench and forming a second insulating film to cover the field plate electrode exposed from the first insulating film after the step (f); and (h) forming a gate electrode on the gate insulating film, on the first insulating film, and on the second insulating film to fill the inner portion of the trench after the step (g). The step (c) includes a step of forming a first oxide film in contact with the semiconductor substrate and a step of forming a second oxide film. In the step (d), the field plate electrode is formed to be in contact with the second oxide film. In the step (f), the first insulating film positioned in the inner portion of the trench is recessed toward the bottom portion of the trench such that an inclination of an upper surface of the first insulating film changes at a boundary between the first oxide film and the second oxide film.

### Eighth Appendix

In the method of manufacturing the semiconductor device according to the seventh appendix, in the step (f), the first insulating film positioned in the inner portion of the trench is recessed toward the bottom portion of the trench such that each of an upper surface of the first oxide film and an upper surface of the second oxide film has a shape that more ascends as being closer from the field plate electrode toward the semiconductor substrate in a cross-sectional view and such that an ascensional rate of the ascension of the upper surface of the first oxide film in a cross-sectional view is higher than an ascensional rate of the ascension of the upper surface of the second oxide film in the cross-sectional view.

### Ninth Appendix

In the method of manufacturing the semiconductor device according to the eighth appendix, the etching process in the step (f) is wet etching process using a predetermined etchant, and an etching rate of the second oxide film for the predetermined etchant is higher than an etching rate of the first oxide film for the predetermined etchant.

### Tenth Appendix

In the method of manufacturing the semiconductor device according to the ninth appendix, the predetermined etchant contains any one of a BHF (buffered hydrofluoric acid), a DHF (dilute hydrofluoric acid), and a gas phase hydrofluoric acid.

### Eleventh Appendix

In the method of manufacturing the semiconductor device according to the tenth appendix, the step of forming the first oxide film in the step (c) includes a step of forming a dry oxide film, and the step of forming the second oxide film in the step (c) includes a step of forming an LPCVD (low-pressure chemical vapor deposition)-TEOS (tetra ethoxy silane) film.

### Twelfth Appendix

In the method of manufacturing the semiconductor device according to the eighth appendix, the step (f) is performed such that an average ascensional angle of the ascension of the upper surface of the first oxide film in the cross-sectional view is 40 degrees or more and 60 degrees or less.

What is claimed is:

1. A semiconductor device comprising:
a semiconductor substrate having an upper surface and a lower surface;
a trench formed in the semiconductor substrate to reach a predetermined depth from the upper surface of the semiconductor substrate toward the lower surface of the semiconductor substrate;
a first insulating film formed from a bottom surface of the trench to a portion of a side surface of the trench;
a gate insulating film connected to the first insulating film and formed on a side surface of the trench;
a field plate electrode formed in an inner portion of the trench through the first insulating film;
a gate electrode formed in the inner portion of the trench through the gate insulating film; and
a second insulating film separating the field plate electrode and the gate electrode from each other,
wherein the first insulating film includes a stacked film made of a first oxide film in contact with the side surface of the trench and a second oxide film in contact with the field plate electrode, and
wherein an inclination of an upper surface of the first insulating film connected to the gate insulating film changes at a boundary between the first oxide film and the second oxide film.

2. The semiconductor device according to claim 1,
wherein each of an upper surface of the first oxide film and an upper surface of the second oxide film has a shape that more ascends as being closer from the field plate electrode toward the semiconductor substrate in a cross-sectional view, and
wherein an ascensional rate of the ascension of the upper surface of the first oxide film in the cross-sectional view is higher than an ascensional rate of the ascension of the upper surface of the second oxide film in the cross-sectional view.

3. The semiconductor device according to claim 2,
wherein an etching rate of the second oxide film for a predetermined etchant is higher than an etching rate of the first oxide film for the predetermined etchant.

4. The semiconductor device according to claim 3,
wherein the predetermined etchant contains any one of a BHF (buffered hydrofluoric acid), a DHF (dilute hydrofluoric acid), and a gas phase hydrofluoric acid.

5. The semiconductor device according to claim 4,
wherein the first oxide film is a dry oxide film, and the second oxide film is an LPCVD (low-pressure chemical vapor deposition)-TEOS (tetra ethoxy silane) film.

6. The semiconductor device according to claim 2,
wherein an average ascensional angle of the ascension of the upper surface of the first oxide film in the cross-sectional view is 40 degrees or more and 60 degrees or less.

7. A method of manufacturing a semiconductor device comprising steps of:
(a) preparing a semiconductor substrate having an upper surface and a lower surface;
(b) after the step (a), forming a trench in the semiconductor substrate to reach a predetermined depth from the upper surface of the semiconductor substrate toward the lower surface of the semiconductor substrate;
(c) after the step (b), forming a first insulating film in an inner portion of the trench and on the upper surface of the semiconductor substrate;
(d) after the step (c), forming a field plate electrode on the first insulating film to fill the inner portion of the trench;
(e) after the step (d), recessing the field plate electrode toward a bottom portion of the trench by etching process;
(f) after the step (e), removing the first insulating film positioned on the upper surface of the semiconductor substrate and recessing the first insulating film positioned in the inner portion of the trench toward the bottom portion of the trench by etching process;
(g) after the step (f), forming a gate insulating film on the upper surface of the semiconductor substrate and in the inner portion of the trench and forming a second insulating film to cover the field plate electrode exposed from the first insulating film; and
(h) after the step (g), forming a gate electrode on the gate insulating film, on the first insulating film, and on the second insulating film to fill the inner portion of the trench,
wherein the step (c) includes a step of forming a first oxide film in contact with the semiconductor substrate and a step of forming a second oxide film,
wherein in the step (d), the field plate electrode is formed to be in contact with the second oxide film, and
wherein in the step (f), the first insulating film positioned in the inner portion of the trench is recessed toward the bottom portion of the trench such that an inclination of an upper surface of the first insulating film changes at a boundary between the first oxide film and the second oxide film.

8. The method of manufacturing the semiconductor device according to claim 7,
wherein in the step (f), the first insulating film positioned in the inner portion of the trench is recessed toward the bottom portion of the trench such that each of an upper surface of the first oxide film and an upper surface of the second oxide film has a shape that more ascends as being closer from the field plate electrode toward the semiconductor substrate in a cross-sectional view and such that an ascensional rate of the ascension of the upper surface of the first oxide film in a cross-sectional view is higher than an ascensional rate of the ascension of the upper surface of the second oxide film in the cross-sectional view.

9. The method of manufacturing the semiconductor device according to claim 8,
wherein the etching process in the step (f) is wet etching process using a predetermined etchant, and
wherein an etching rate of the second oxide film for the predetermined etchant is higher than an etching rate of the first oxide film for the predetermined etchant.

10. The method of manufacturing the semiconductor device according to claim 9,
wherein the predetermined etchant contains any one of a BHF (buffered hydrofluoric acid), a DHF (dilute hydrofluoric acid), and a gas phase hydrofluoric acid.

11. The method of manufacturing the semiconductor device according to claim 10,
wherein the step of forming the first oxide film in the step (c) includes a step of forming a dry oxide film, and
wherein the step of forming the second oxide film in the step (c) includes a step of forming an LPCVD (low-pressure chemical vapor deposition)-TEOS (tetra ethoxy silane) film.

12. The method of manufacturing the semiconductor device according to claim 8,
wherein the step (f) is performed such that an average ascensional angle of the ascension of the upper surface of the first oxide film in the cross-sectional view is 40 degrees or more and 60 degrees or less.
